(19) United States
(12) Patent Application Publication
(10) Pub. No.: US 2013/0089665 A1
(43) Pub. Date: Apr. 11, 2013

(54) SELF-LIMITING REACTION DEPOSITION APPARATUS AND SELF-LIMITING REACTION DEPOSITION METHOD

(71) Applicants: Hiroya Takenaka, Kanagawa (JP); Ryoichi Hiratsuka, Miyagi (JP); Masaaki Sekine, Kanagawa (JP); Takuji Matsuo, Kanagawa (JP); Hidetoshi Honda, Kanagawa (JP)

(72) Inventors: Hiroya Takenaka, Kanagawa (JP); Ryoichi Hiratsuka, Miyagi (JP); Masaaki Sekine, Kanagawa (JP); Takuji Matsuo, Kanagawa (JP); Hidetoshi Honda, Kanagawa (JP)

(73) Assignee: SONY CORPORATION, Tokyo (JP)

(21) Appl. No.: 13/615,737

(22) Filed: Sep. 14, 2012

(30) Foreign Application Priority Data
Oct. 7, 2011 (JP) 2011-222579

(51) Int. Cl. C23C 16/54; C23C 16/46; C23C 16/458

(52) U.S. Cl. 427/248.1; 118/718

(57) ABSTRACT

A self-limiting reaction deposition apparatus includes a first guide roller, a second guide roller, and at least one first head. The first guide roller changes, while supporting a first surface of a base material conveyed by a roll-to-roll process, a conveying direction of the base material from a first direction to a second direction that is not parallel to the first direction. The second guide roller changes, while supporting the first surface of the base material, the conveying direction of the base material from the second direction to a third direction that is not parallel to the second direction. The at least one first head is disposed between the first guide roller and the second guide roller, faces a second surface opposite to the first surface of the base material, and discharges, towards the second surface, a raw material gas for self-limiting reaction deposition.

### CROSS REFERENCES TO RELATED APPLICATIONS

The present disclosure contains subject matter related to that disclosed in Japanese Priority Patent Application JP 2011-222579 filed in the Japan Patent Office on Oct. 7, 2011, the entire content of which is hereby incorporated by reference.

### BACKGROUND

The present disclosure relates to a self-limiting reaction deposition apparatus and a self-limiting reaction deposition method that form a film by using an Atomic Layer Deposition (ALD) method or a Molecular Layer Deposition (MLD) method.

As a thin film deposition technique, the ALD method has been known. The ALD method is a technique for depositing a thin film by sequential chemical reactions of reactive gases. In the ALD method, two types of reactive gases (raw material gases), each of which is called a precursor gas, are used normally. Each of the precursor gases reacts on a base material surface by being separately exposed to the base material surface and forms the thin film in a unit of an atomic layer per one cycle. Therefore, by repeated reactions of each of the precursor gases on the base material surface, the thin film having a predetermined thickness is formed.

As a deposition apparatus that uses the ALD method, for example, a deposition apparatus that uses a roll-to-roll process has been known. For example, Japanese Unexamined Patent Application Publication No. 2007-522344 discloses an atomic layer deposition apparatus provided with a rotatable drum, a peripheral surface of which is wound up with a polymer substrate, and a plurality of ALD sources that are disposed along a circumference of the drum and discharge a raw material gas on the polymer substrate. Moreover, Japanese Patent Application Laid-open No. 2011-137208 discloses a deposition apparatus provided with a conveying mechanism of a base material including a plurality of roll members, and a plurality of head portions each of which is disposed so as to face the plurality of roll members and is capable of locally discharging, towards the base material, a precursor gas for performing an ALD process.

### SUMMARY

As described in Japanese Unexamined Patent Application Publication No. 2007-522344 and Japanese Patent Application Laid-open No. 2011-137208, in the deposition apparatus that uses the ALD sources or the head portions as a source of supply of the raw material gas, it is necessary to ensure a predetermined fine clearance between the ALD sources or the head portions and the base material surface so that a plurality of raw material gases are not mixed with each other.

However, in the deposition apparatuses disclosed in Japanese Unexamined Patent Application Publication No. 2007-522344 and Japanese Patent Application Laid-open No. 2011-137208, because the ALD sources or the head portions are disposed so as to face an arc-like peripheral surface of the drum or the roll members, it may be impossible to form the predetermined clearance between the ALD sources or the head portions and the base material surface. Therefore, there is a problem that it is difficult to stably form a film in the above-mentioned deposition apparatuses.

In view of the circumstances as described above, there is a need for a self-limiting reaction deposition apparatus and a self-limiting reaction deposition method that are capable of increasing the stability of deposition.

According to an embodiment of the present disclosure, there is provided a self-limiting reaction deposition apparatus including a first guide roller, a second guide roller, and at least one first head.

The first guide roller is configured to change, while supporting a first surface of a base material conveyed by a roll-to-roll process, a conveying direction of the base material from a first direction to a second direction that is not parallel to the first direction.

The second guide roller is configured to change, while supporting the first surface of the base material, the conveying direction of the base material from the second direction to a third direction that is not parallel to the second direction.

The at least one first head is disposed between the first guide roller and the second guide roller, faces a second surface opposite to the first surface of the base material, and is configured to discharge, towards the second surface, a raw material gas for self-limiting reaction deposition.

In the self-limiting reaction deposition apparatus, the first surface of the base material is supported by the first guide roller and the second guide roller, and the base material is linearly bridged between the first guide roller and the second guide roller. On the other hand, the at least one first head is disposed between the first guide roller and the second guide roller and thus faces the base material in a horizontal direction. Accordingly, since a clearance between the base material and the at least one first head can be kept in a predetermined size, it is possible to stably form an atomic layer or a molecular layer on the second surface of the base material.

The number of the at least one first head that is disposed between the first guide roller and the second guide roller may be one or at least two. The at least one first head may be configured to discharge, by itself, a plurality of types of gases that are necessary for an atomic layer deposition process. Alternatively, the at least one first head may be configured by combining a plurality of head portions that individually discharge a plurality of types of gases necessary for the atomic layer deposition process or a molecular layer deposition process.

For example, the at least one first head may include a gas discharging surface. The gas discharging surface includes a plurality of head portions capable of individually discharging a plurality of types of raw material gases and is parallel to the second direction. In this case, the at least one first head forms a thin film on the second surface between the first guide roller and the second guide roller. The thin film has at least one atomic layer.

Accordingly, it is possible to stably form the thin film having at least one atomic layer on the base material.

The self-limiting reaction deposition apparatus may further includes a heater unit. The heater unit is disposed so as to face the first head across the base material and is configured to be capable of heating the base material to a predetermined temperature.

Accordingly, since a deposition area of the base material can be stably heated to a predetermined deposition temperature, it is possible to improve a film quality of the atomic layer or the molecular layer.

A configuration of the heater unit is not particularly limited and only needs to be capable of heating the base material through conduction, convection, or emission. For example, the heater unit includes a discharge unit that is configured to discharge, towards the second surface of the base material, fluid heated to a predetermined temperature. Accordingly, it is possible to suppress looseness of the base material by pressure of fluid, while heating the deposition area of the base material, and stably maintain the predetermined clearance between the base material and the at least one first head.

The self-limiting reaction deposition apparatus may further include a third guide roller and a second head.

The third guide roller is configured to change, while supporting the first surface, the conveying direction of the base material from the third direction to a fourth direction that is not parallel to the third direction.

The second head is disposed between the second guide roller and the third guide roller, faces the second surface of the base material, and is configured to discharge, towards the second surface, the raw material gas for self-limiting reaction deposition.

In the above-mentioned configuration, the second head may be configured to discharge the same gas as the raw material gas discharged from the at least one first head or a gas different from the raw material gas discharged from the at least one first head. Specifically, the second head may form an atomic layer or a molecular layer including the same material as that of the atomic layer or the molecular layer formed by the at least one first head. Alternatively, the second head may form an atomic layer or a molecular layer including a material different from that of the atomic layer or the molecular layer formed by the at least one first head.

On the other hand, according to another embodiment of the present disclosure, there is provided a self-limiting reaction deposition apparatus including a first roller group and a plurality of first heads.

The first roller group includes a plurality of first guide rollers that are arranged so as to change, while supporting a first surface of a base material conveyed by a roll-to-roll process, a conveying direction of the base material in a stepwise manner.

The plurality of first heads each are disposed between predetermined first guide rollers among the plurality of first guide rollers, face a second surface opposite to the first surface of the base material, and are configured to discharge, towards the second surface, a raw material gas for self-limiting reaction deposition.

In the self-limiting reaction deposition apparatus, the first surface of the base material is supported by the plurality of first guide rollers, and the base material is linearly bridged between the plurality of first guide rollers. On the other hand, the plurality of first heads are disposed between the plurality of first guide rollers and thus face the second surface of the base material in the horizontal direction. Accordingly, since a clearance between the base material and each of the plurality of first heads can be stably ensured, it is possible to stably form the atomic layer or the molecular layer on the second surface of the base material. Moreover, since the atomic layer or the molecular layer is formed by the plurality of first heads, it is possible to improve productivity.

The self-limiting reaction deposition apparatus may further include a second roller group and a plurality of second heads.

The second roller group includes a plurality of second guide rollers that are arranged so as to change, while supporting the second surface of the base material, the conveying direction of the base material in a stepwise manner.

The plurality of second heads each are disposed between predetermined second guide rollers among the plurality of second guide rollers, face the first surface of the base material, and are configured to discharge, towards the first surface, the raw material gas for self-limiting reaction deposition.

Accordingly, not only on the first surface of the base material but also on the second surface of the base material, the atomic layer or the molecular layer can be formed.

In this case, the self-limiting reaction deposition apparatus may further include a processing unit. The processing unit is disposed between the first roller group and the second roller group and is configured to perform a dust removing operation on the first surface of the base material and the second surface of the base material.

Accordingly, since the first surface of the base material and the second surface of the base material can be cleaned, it is possible to stably form, on both surfaces of the base material, an atomic layer or a molecular layer with high quality.

The self-limiting reaction deposition apparatus may further include an unwind roller configured to supply the base material to the first roller group and a wind-up roller configured to wind up the base material to be fed out from the first roller group.

Accordingly, since sequential deposition can be performed on the base material, it is possible to improve productivity.

The self-limiting reaction deposition apparatus may further include a chamber configured to house the first roller group and the plurality of first heads.

Accordingly, it is possible to freely adjust a deposition atmosphere of the base material. An atmosphere in the chamber may be air or reduced pressure atmosphere. Alternatively, the atmosphere in the chamber may be replaced as a predetermined inert gas atmosphere.

A self-limiting reaction deposition method according to an embodiment of the present disclosure includes conveying, while supporting a first surface of a base material conveyed by a roll-to-roll process by a plurality of guide rollers, the base material so as to change a conveying direction in a stepwise manner.

By discharging a raw material gas for self-limiting reaction deposition from a plurality of heads each of which is disposed between predetermined guide rollers among the plurality of guide rollers, thin films having at least one atomic layer are successively formed on a second surface opposite to the first surface of the base material.

In the self-limiting reaction deposition method, the first surface of the base material is supported by the plurality of guide rollers, and the base material is linearly bridged between the plurality of guide rollers. On the other hand, the plurality of heads are disposed between the plurality of guide rollers and thus face the second surface of the base material in the horizontal direction. Accordingly, since a predetermined clearance between the base material and each of the plurality of heads can be stably ensured, it is possible to stably form the atomic layer or the molecular layer on the second surface of the base material. Moreover, since the atomic layer or the molecular layer is sequentially formed by the plurality of heads, it is possible to improve productivity.

As described above, according to the embodiments of the present disclosure, it is possible to stably form an atomic layer or a molecular layer on a base material.

Additional features and advantages are described herein, and will be apparent from the following Detailed Description and the figures.

### BRIEF DESCRIPTION OF THE FIGURES

FIG. 1 is a schematic configuration diagram of a self-limiting reaction deposition apparatus according to a first embodiment of the present disclosure;

FIG. 2 is a schematic diagram showing a conveying path of a base material by guide rollers in the self-limiting reaction deposition apparatus;

FIG. 3 is a schematic diagram showing a relationship between ALD heads and the base material in the self-limiting reaction deposition apparatus;

FIG. 4 is a schematic cross-sectional view showing a configuration of heater units in the self-limiting reaction deposition apparatus;

FIGS. 5A to 5D are schematic process drawings for explaining a self-limiting reaction deposition method that uses the ALD heads;

FIG. 6 is a schematic cross-sectional view showing a configuration example of a film device made by the self-limiting reaction deposition apparatus;

FIG. 7 is a schematic configuration diagram of a self-limiting reaction deposition apparatus according to a second embodiment of the present disclosure;

FIG. 8 is a schematic cross-sectional view showing a configuration example of a film device made by the self-limiting reaction deposition apparatus;

FIG. 9 is a schematic configuration diagram of a self-limiting reaction deposition apparatus according to a third embodiment of the present disclosure;

FIG. 10 is a schematic configuration diagram of a self-limiting reaction deposition apparatus according to a fourth embodiment of the present disclosure; and

FIG. 11 is a main portion schematic diagram for illustrating an alternative example of the embodiments of the present disclosure.

### DETAILED DESCRIPTION

Embodiments of the present application will be described below in detail with reference to the drawings.

Hereinafter, embodiments according to the present disclosure will be described with reference to the drawings. In the following embodiments, as an example of self-limiting reaction deposition apparatus, an atomic layer deposition (ALD) apparatus will be described.

### First Embodiment

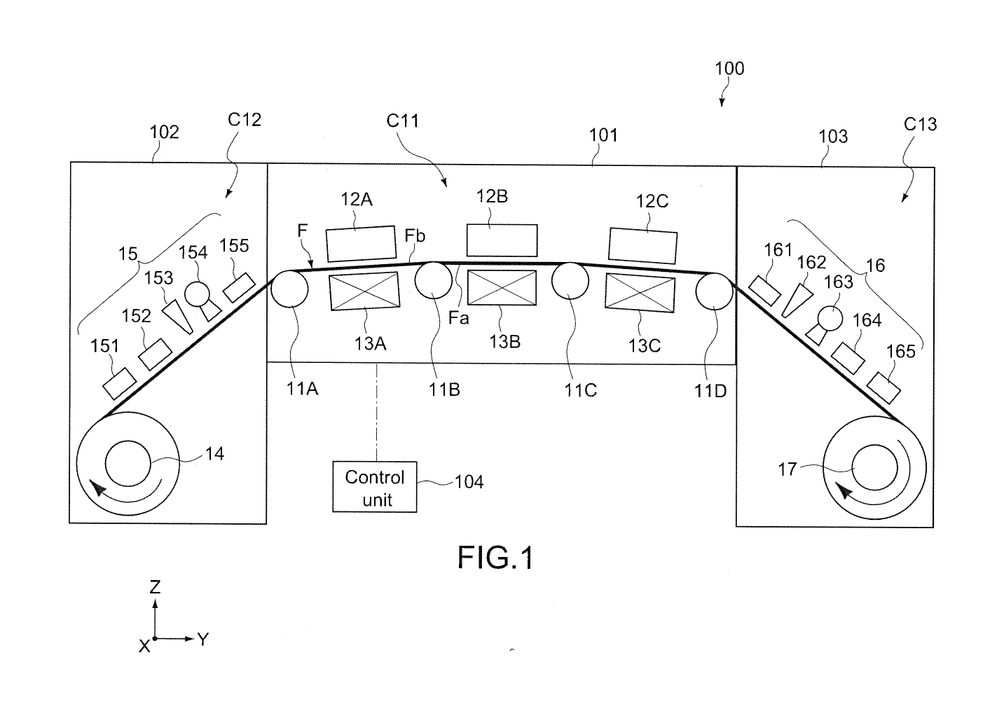

FIG. 1 is a schematic configuration diagram of an atomic layer deposition apparatus according to a first embodiment of the present disclosure. In FIG. 1, an X-axis and a Y-axis indicate horizontal directions perpendicular to each other, and a Z-axis indicates a vertical direction. In this embodiment, an atomic layer deposition apparatus and an atomic layer deposition method that deposit an atomic layer on one surface of a base material to be conveyed by a roll-to-roll process will be described.

[Entire Configuration of Atomic Layer Deposition Apparatus]

An atomic layer deposition apparatus 100 according to this embodiment includes a first chamber 101, a second chamber 102, and a third chamber 103. In the first chamber 101, a deposition unit C11 including guide rollers, ALD heads, and the like, is housed. In the second chamber 102, an unwind unit C12 including an unwind roller, which supplies a base material F to the deposition unit C11, and the like, is housed. In the third chamber 103, a wind-up unit C13 including a wind-up roller, which winds up the base material F from the deposition unit C11, and the like is housed. Between the first chamber 101 and the second chamber 102, and between the first chamber 101 and third chamber 103, respective openings through which the base material F passes are formed.

Each of the first to third chambers, 101 to 103, is configured to be capable of evacuating air inside the chamber by a vacuum pump (not shown). A common vacuum pump may evacuate air inside the chambers 101 to 103, or a plurality of vacuum pumps that are connected individually may evacuate air inside each of the chambers.

The atomic layer deposition apparatus 100 includes a gas conducting line capable of conducting, to the first to third chambers, 101 to 103, a predetermined process gas such as nitrogen and argon, and is configured to be capable of maintaining each of the chambers in a predetermined gas atmosphere.

The base material F includes a long plastic film or a long sheet that has flexibility and is cut to a predetermined width. Examples of the plastic film include a film having translucency such as polyethylene terephthalate (PET), polyethylene naphthalate (PEN), polycarbonate (PC), polyether sulfone (PES), polystyrene (PS), aramid, triacetyl cellulose (TAC), cyclo-olefin polymer (COP), and polymethyl methacrylate (PMMA). The base material F is not limited to the plastic film, and a metal film such as aluminum, stainless steel, and titanium, a glass film, or the like, may be employed as the base material F.

[Deposition Unit]

(Guide Roller)

The deposition unit C11 includes a plurality of guide rollers 11A, 11B, 11C, and 11D that are arranged so as to change a conveying direction of the base material F in a stepwise manner while supporting a first surface of the base material F to be conveyed by a roll-to-roll process. The guide rollers 11A to 11D include a rotatable roll member supporting a back surface Fb (first surface) of the base material F and arranged so as to change the conveying direction of the base material F in a stepwise manner. The guide rollers 11A to 11D have a cylindrical shape whose central axis is in an X-axis direction.

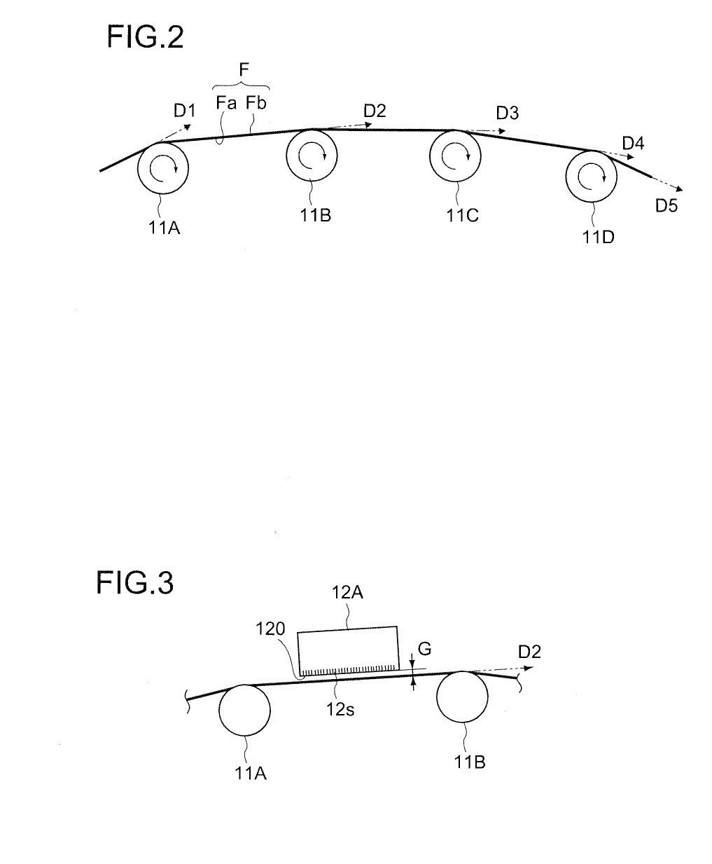

FIG. 2 is a schematic diagram showing a conveying path of the base material F by the guide rollers 11A to 11D. The guide roller 11A is located at the upstream side of the conveying direction of the base material F in the deposition unit C11 and changes, from a direction D1 to a direction D2, the conveying direction of the base material F supplied from the unwind unit C12. The guide roller 11B is located immediately downstream of the guide roller 11A and changes the conveying direction of the base material F from the direction D2 to a direction D3. The guide roller 11C is located immediately downstream of the guide roller 11B and changes the conveying direction of the base material F from the direction D3 to a direction D4. The guide roller 11D is located immediately downstream of the guide roller 11C, changes the conveying direction of the base material F from the direction D4 to a direction D5 and then sends the base material F to the wind-up unit C13.

Here, the direction D1 and the direction D2, the direction D2 and the direction D3, the direction D3 and the direction D4, and the direction D4 and the direction D5 are in a non-parallel relationship to each other. Accordingly, it is possible to apply, to the base material F, tension determined depending on a crimp angle of the base material F in the guide rollers 11A to 11D, and achieve a linear conveying position of the base material F among the plurality of guide rollers adjacent to each other.

Arrangement intervals of the guide rollers 11A to 11D are not particularly limited and set so that the linear conveying position of the base material F is not varied by weight of the base material F. Also the crimp angle of the base material F in each of the guide rollers 11A to 11D is not particularly limited and only needs to be 1 degree or more, for example.

Each of the guide rollers 11A to 11D has an independent rotating drive source but may include a free roller having no its own driving source. Since each of the guide rollers 11A to 11D is configured to be capable of driving individually, it is possible to optimize the tension of the base material F in each of the guide rollers. A driving method is not particularly limited and may be a speed control or a torque control. A peripheral surface of the guide rollers 11A to 11D that come into contact with the base material F is typically formed of a metal material. The peripheral surface is not limited to the metal material and may be formed of an insulating material or the like.

In the deposition unit C11, the number of guide rollers that guide a run of the base material F is not limited to the example described above, and a plurality of guide rollers may be used additionally.

(ALD Head)

The deposition unit C11 further includes a plurality of ALD heads 12A, 12B, and 12C for depositing an atomic layer on the base material F. The ALD heads 12A to 12C are successively disposed along the conveying direction of the base material F and are configured to be capable of discharging, towards a front surface Fa (second surface) of the base material F, various raw material gases for atomic layer deposition.

The type of the raw material gas is set depending on the type of a thin film to be formed. In this embodiment, on the front surface Fa of the base material F, an atomic layer of aluminum oxide (Al₂O₃) is formed. In this case, a first precursor gas and a second precursor gas are used. Examples of the first precursor gas include trimethylaluminium (TMA; (CH₃)₃Al) and the like. Examples of the second precursor gas include water (H₂O) and the like. Also, as a purge gas, nitrogen (N₂) or the like is used.

It should be noted that, as these precursor gases, in addition to the materials described above, the following materials may be used, for example.

B is(tert-butylimino)bis(dimethylamino)tungsten(VI); ((CH₃)₃CN)₂W(N(CH₃)₂)₂

Tris(tert-butoxy)silanol; ((CH₃)₃CO)₃SiOH

Diethyl zinc; (C₂H₅)₂Zn

Tris(diethylamino)(tert-butylimino)tantalum(V); (CH₃)₃CNTa(N(C₂H₅)₂)₃

Tris(tert-pentoxy)silanol; (CH₃CH₂C(CH₃)₂O)₃SiOH

Trimethyl(methylcyclopentadienyl)platinum(IV); C₅H₄CH₃Pt(CH₃)₃

Bis(ethylcyclopentadienyl)ruthenium(II); C₇H₉RuC₇H₉

(3-aminopropyl)triethoxysilane; H₂N(CH₂)₃Si(OC₂H₅)₃

Silicon tetrachloride; SiCl₄

Titanium tetrachloride; TiCl₄

Titanium(IV) isopropoxide; Ti[(OCH)(CH₃)2]₄

Tetrakis(dimethylamino)titanium(IV); [(CH₃)₂N]₄Ti

Tetrakis(dimethylamino)zirconium(IV); [(CH₃)₂N]₄Zr

Tris[bis(trimethylsilyl)amino]yttrium; ([[(CH₃)₃Si]₂]N)₃Y

The ALD head 12A is disposed between the guide roller 11A and the guide roller 11B, and forms an atomic layer of aluminum oxide on the front surface Fa of the base material F to be conveyed from the guide roller 11A to the guide roller 11B. The ALD head 12B is disposed between the guide roller 11B and the guide roller 11C, and forms an atomic layer of aluminum oxide on the front surface Fa of the base material F to be conveyed from the guide roller 11B to the guide roller 11C. Then, the ALD head 12C is disposed between the guide roller 11C and the guide roller 11D, and forms an atomic layer of aluminum oxide on the front surface Fa of the base material F to be conveyed from the guide roller 11C to the guide roller 11D. Hereinafter, the atomic layer to be formed by each of the ALD heads 12A to 12C is referred to also as “ALD film”.

FIG. 3 is a schematic diagram showing a relationship between the ALD head 12A and the base material F. The ALD head 12A includes a gas discharging surface 120 that discharges various raw material gases including, as the raw material gas, the first precursor gas, the second precursor gas, and the purge gas. The gas discharging surface 120 is formed of a substantially flat surface and is disposed so as to face the front surface Fa of the base material F. In the ALD head 12A, since the gas discharging surface 120 is disposed so as to be in parallel with the front surface Fa of the base material F that runs in the direction D2, a predetermined gap (clearance) G is formed between the gas discharging surface 120 and the front surface Fa of the base material F. The size of the gap G is not particularly limited and may be set to be 2 mm, for example.

On the gas discharging surface 120, a plurality of spouts (head portions) 12s that discharge the various raw material gases are formed. These spouts 12s include a plurality of slits arranged along the conveying direction of the base material F. For example, a first slit that discharges the first precursor gas, a second slit that discharges the purge gas, a third slit that discharges the second precursor gas, and a fourth slit that discharges the purge gas are arranged in the stated order in the conveying direction of the base material F. These raw material gases may typically be discharged from each of the slits. Alternatively, a discharging time may be adjusted individually. Moreover, in order to prevent the gasses from being mixed with each other, a slit for suction may be provided at an appropriate position on the gas discharging surface 120.

The number of sets of the first to fourth slits that are formed on the gas discharging surface 120 may be one. In this embodiment, however, a plurality of sets of the first to fourth slits are repeatedly arranged on the gas discharging surface 120. Accordingly, since an ALD film formed of multiple atomic layers can be formed by a single ALD head 12A, it is possible to improve productivity.

Also the other ALD heads 12B and 12C each have the same configuration as that of the ALD head 12A described above. A gas discharging surface of the ALD head 12B is disposed so as to be in parallel with the front surface Fa of the base material F that runs in the direction D3. A gas discharging surface of the ALD head 12C is disposed so as to be in parallel with the front surface Fa of the base material F that runs in the direction D4. Each of the sizes of the gaps G between the ALD heads 12B and 12C and the base material F may be set to be the same value as that of the gap G between the ALD head 12A and the base material F, or a different value from that of the gap G between the ALD head 12A and the base material F. Moreover, the ALD heads 12B and 12C are configured so as to form an ALD film formed of aluminum oxide by discharging the same raw material gas as that of the ALD head 12A but are not limited to this. An ALD film formed of a material other than aluminum oxide may be formed.

The number of the ALD heads is not limited to the above-mentioned example and can be set as appropriate so that an ALD film having a desired thickness can be obtained, for example.

(Heater Unit)

The deposition unit C11 further includes a plurality of heater units 13A, 13B, and 13C for heating the base material F to a predetermined temperature. The heater units 13A to 13C are disposed between the guide rollers 11A and 11B, between the guide rollers 11B and 11C, and between the guide rollers 11C and 11D, respectively, and face the back surface Fb of the base material F. The heater units 13A to 13C are disposed so as to face the ALD heads 12A to 12C across the base material F, respectively, and individually heat the deposition area of the base material F that faces the ALD heads 12A to 12C.

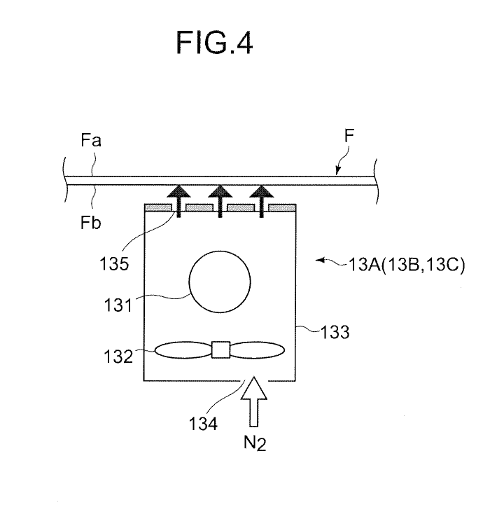

Configurations of the heater units 13A to 13C are not particularly limited, and an appropriate configuration may be employed depending on a heating system. This embodiment employs a mechanism that the inside of the first chamber 101 is maintained in a nitrogen gas atmosphere under predetermined pressure and the heater units 13A to 13C discharge, towards the back surface Fb of the base material F, hot air heated to a predetermined temperature as shown in FIG. 4.

FIG. 4 is a schematic cross-sectional view showing a configuration of the heater unit 13A. The other heater units 13B and 13C each have the same configuration as that of the heater unit 13A. The heater unit 13A includes a casing 133 that houses a heater 131, a fan 132, and the like. The casing 133 includes an inlet 134 for sucking a nitrogen gas inside the first chamber 101 and a plurality of discharge nozzles 135 that discharge the nitrogen gas. The heater unit 13A sucks, by rotations of the fan 132, the nitrogen gas from the inlet 134 to the inside of the casing 133, and discharges, from the discharge nozzle 135 to the back surface Fb of the base material F, the nitrogen heated to a predetermined temperature by the heater 131. The heating temperature of the base material F is not particularly limited but may be 200° C., for example.

According to the heater units 13A to 13C having the above-mentioned configuration, it is possible not only to heat the base material F to a predetermined temperature but also to prevent looseness of the base material F by pressure of fluid (nitrogen) to be discharged. Accordingly, fluctuation of the gap G caused due to the looseness of the base material F can be prevented. Alternatively, by discharge pressure of the nitrogen gas, the gaps G between the base material F and the ALD heads 12A to 12C may be set to be a desired value.

[Supply Unit]

The unwind unit C12 includes an unwind roller 14 that unwinds the base material F and a pre-processing unit 15 that applies pre-processing to the base material F before deposition.

The unwind roller 14 includes a driving source that is capable of controlling the number of rotations and successively sends the base material F to the deposition unit C11 at a predetermined line speed (conveying speed). The unwind unit C12 may further include one or more guide rollers that guide the run of the base material F supplied from the unwind roller 14. The unwind unit C12 supplies, along the direction D1, the base material F to the guide roller 11 A of the deposition unit C11.

The pre-processing unit 15 includes a surface processing unit 151, a dust/electricity removing processing unit 152, an ultraviolet (UV) cured resin discharge unit 153, a UV irradiation unit 154, a preheating unit 155, and the like, which are selectively used depending on a type (layer construction) of a device to be made, a processing condition, and the like. For example, when a water vapor barrier film is made, as a base of an ALD film formed of aluminum oxide, a UV resin layer is formed on the front surface Fa of the base material F.

[Collection Unit]

On the other hand, the wind-up unit C13 includes a post-processing unit 16 that applies post-processing to the base material F after deposition and a wind-up roller 17 that winds up the base material F.

The wind-up roller 17 includes a driving source that is capable of controlling the number of rotations and successively winds up the base material F from the deposition unit C11 at a predetermined line speed. The wind-up unit C13 may include one or more guide rollers that guide the run of the base material F that has been conveyed from the guide roller 11D of the deposition unit C11.

The post-processing unit 16 includes a preheating unit 161, a UV cured resin discharge unit 162, a UV irradiation unit 163, a dust/electricity removing processing unit 164, a surface processing unit 165, and the like, which are selectively used depending on a type (layer construction) of a device to be made, a processing condition, and the like. For example, when a water vapor barrier film is made, as a top coat fowled of aluminum oxide, a UV resin layer is formed on an ALD film. The dust/electricity removing processing unit 164 is applied to prevent collapse of coil by performing a dust removing operation or an electricity removing operation on the base material F before winding up. The preheating unit 161 and the surface processing unit 165 are applied when, for example, driving the wind-up roller 17 as an unwind roller and resupplying the base material F to the deposition unit C11 after winding up the base material F.

[Control Unit]

It should be noted that the atomic layer deposition apparatus 100 includes a control unit 104 (FIG. 1) that controls driving of the respective units, e.g., the deposition unit C11, the unwind unit C12, and the wind-up unit C 13. The control unit 104 typically includes a computer and controls rotary driving of the unwind roller 14, the guide rollers 11A to 11D, and the wind-up roller 17, gas discharge of the ALD heads 12A to 12C, temperature regulation or fluid discharge pressure of the heater units 13A to 13C, and the like.

[Atomic Layer Deposition Method]

Next, an atomic layer deposition method that uses the above-mentioned atomic layer deposition apparatus 100 will be described.

The inside of the first to third chambers 101 to 103 is maintained in nitrogen gas atmosphere adjusted to predetermined pressure. The atomic layer deposition apparatus 100 applies predetermined pre-processing in the unwind unit C12, forms an ALD film in the deposition unit C11, and applies predetermined post-processing in the wind-up unit C13, while conveying the base material F at a predetermined conveying speed between the unwind roller 14 and the wind-up roller 17. Hereinafter, deposition processing in the deposition unit C11 will be described mainly.

The atomic layer deposition apparatus 100 conveys the base material F so as to change the conveying direction in a stepwise manner, as shown in FIG. 2, while supporting the back surface Fb of the base material F by the guide rollers 11A to 11D. Accordingly, it is possible to apply, to the base material F, predetermined tension between the guide rollers 11A to 11D adjacent to each other, and stably hold a linear conveying position of the base material F.

The heater units 13A to 13C heat the base material F to a predetermined temperature (e.g., 200° C.) by blasting the nitrogen heated to a predetermined temperature on the back surface Fb of the base material F. Moreover, by applying predetermined fluid pressure to the back surface Fb of the base material F, rattling of the base material F during the run can be suppressed, and stability of a running position of the base material F can be improved.

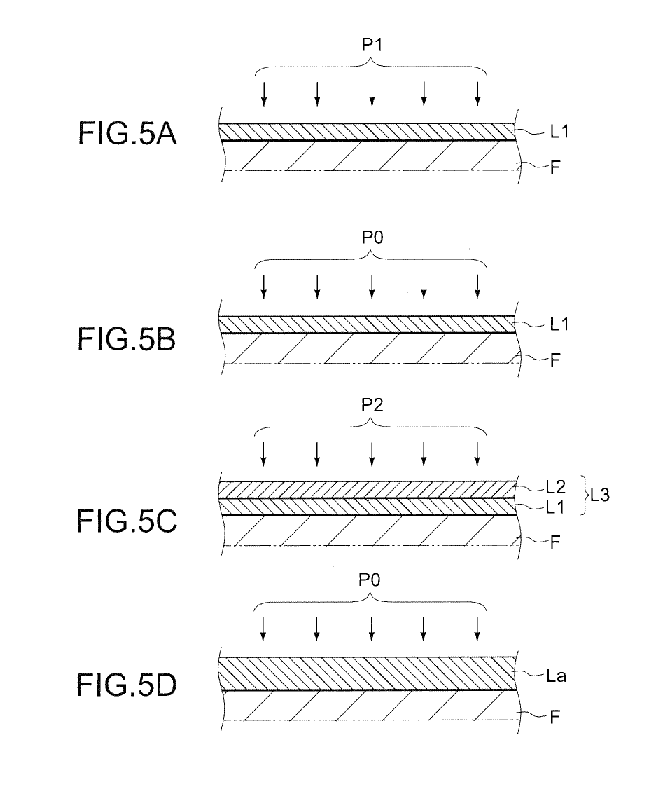

The ALD heads 12A to 12C each form an ALD layer formed of aluminum oxide by discharging, towards the front surface Fa of the base material F, the first precursor gas, the purge gas, the second precursor gas, and the purge gas in the stated order. FIGS. 5A to 5D each schematically show a deposition process of an ALD layer by the ALD head 12a.

As shown in FIG. 5A, when a front surface of the base material F is exposed to a first precursor gas (e.g., TMA) P1, the first precursor gas P1 is adsorbed on the surface of the base material F and thus a first precursor layer L1 including the first precursor gas P1 is formed on the surface of the base material F. Next, as shown in FIG. 5B, the surface of the base material F is exposed to a purge gas P0, and the first precursor gas P1 that is not bonded to the surface of the base material F and is remained on the surface of the base material F is removed. As the purge gas P0, in a case where an ALD layer formed of aluminum oxide is formed, nitrogen or argon is used. However, in addition to these gases, hydrogen, oxygen, carbon dioxide, or the like, may be used as the purge gas P0.

Next, as shown in FIG. 5C, the surface of the base material F is exposed to a second precursor gas (e.g., H2O) P2. The second precursor gas P2 is adsorbed on the surface of the base material F, and thus a second precursor layer L2 including the second precursor gas P2 is formed on the first precursors layer L1. As a result, by a chemical reaction between the first precursor layer L1 and the second precursor layer L2, a monolayer L3 of aluminum oxide is formed. After that, as shown in FIG. 5D, the purge gas P0 is resupplied on the surface of the base material F and thus the second precursor gas P2 that is not bonded to the surface of the base material F and is remained on the surface of the base material F is removed.

The above-mentioned processing is repeated in a plurality of cycles during passing of the ALD head 12a, and thus, on the front surface Fa of the base material F, an ALD layer La including a multilayer of aluminum oxide is formed. According to this embodiment, since a self-limiting mechanism of a surface chemical reaction during a deposition process by chemical reactions is operated, it is possible to perform uniform layer control at an atomic layer level and form, on the surface of the base material F, a film having a high film quality and high step coverage. Moreover, since the above-mentioned processing is repeated a plurality of times every time the base material F passes under the ALD heads 12A to 12C, efficiency for deposition can be improved. Since a plurality of ALD heads that perform such processing are provided, an ALD layer having a desired thickness can be easily formed.

In this embodiment, since the ALD heads 12A to 12C are disposed between the guide rollers 11A and 11B, between the guide rollers 11B and 11C, and between the guide rollers 11C and 11D, respectively, it is possible to dispose the gas discharging surface 120 of each of the ALD heads 12A to 12C on the front surface Fa of the base material F to be conveyed linearly so as to face each other in the horizontal direction. Accordingly, the gap (clearance) G to be formed between the front surface Fa of the base material F and the gas discharging surface 120 can be maintained to be a predetermined value, and stability of deposition of an ALD layer can be improved. Moreover, since the ALD heads 12A to 12C are arranged in series with respect to the conveying direction of the base material F, productivity can be improved.

Moreover, according to this embodiment, since a deposition surface (front surface Fa) of the base material F is configured not to be brought into contact with the guide rollers 11A to 11D, it is possible to avoid that a deposition layer (ALD layer) is scratched or is attached with dust. Accordingly, an ALD layer of a high quality can be stably formed.

Furthermore, according to this embodiment, the deposition unit C11, the unwind unit C12, and the wind-up unit C13 can be adjusted to different atmospheres according to a deposition condition, because the first to third chambers 101 to 103 each are configured of an independent chamber. Accordingly, the degree of freedom for setting the processing condition can be enhanced depending on the type of the device to be made.

[Film Device]

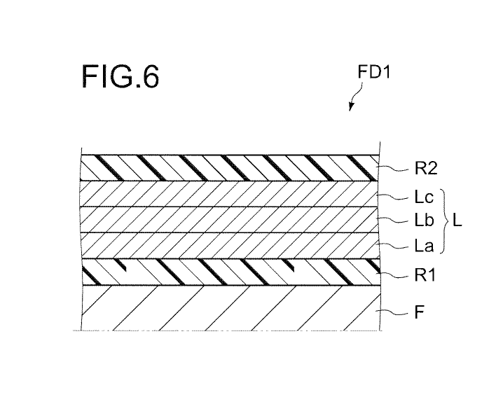

FIG. 6 is a schematic cross-sectional view showing a configuration example of a film device made by the atomic layer deposition apparatus 100. A film device FD1 shown in the figure has a laminate configuration in which, on the surface of the base material F, a base layer (under coat layer) R1, the ALD layer La, ALD layers Lb and Lc, and a protective layer (top coat layer) R2 are formed in the stated order.

The base layer R1 includes UV cured resin made by passing through the UV cured resin discharge unit 153 and the UV irradiation unit 154 in the unwind unit C12. The ALD layer La is a multilayer including aluminum oxide formed by passing through the ALD head 12A in the deposition unit C11. Similarly, the ALD layers Lb and Lc are multilayers including aluminum oxide formed by passing through the ALD heads 12B and 12C, respectively. The protective layer R2 includes UV cured resin formed by passing through the UV cured resin discharge unit 162 and the UV irradiation unit 163 in the wind-up unit C 13. A film device having such a configuration may be applied as a water vapor barrier film, for example.

### Second Embodiment

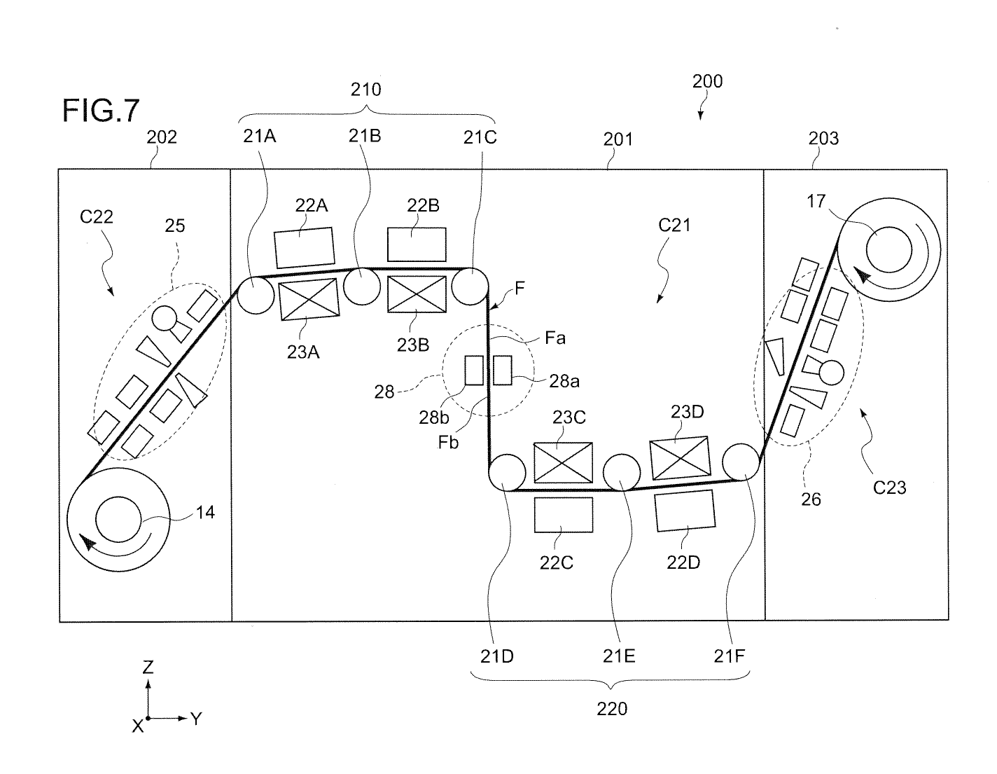

FIG. 7 is a schematic configuration diagram of an atomic layer deposition apparatus according to a second embodiment of the present disclosure. In this embodiment, a description of the same configuration and operation as those according to the first embodiment will be omitted or simplified, and a different component from the first embodiment will be described mainly.

An atomic layer deposition apparatus 200 includes a first chamber 201, a second chamber 202, and a third chamber 203. In the first chamber 201, a deposition unit C21 including guide rollers, ALD heads, and the like is housed. In the second chamber 202, an unwind unit C22 including an unwind roller, which supplies the base material F to the deposition unit C21, and the like is housed. In the third chamber 203, a wind-up unit C23 including a wind-up roller, which winds up the base material F from the deposition unit C21, and the like is housed. Between the first chamber 201 and the second chamber 202, and between the first chamber 201 and the third chamber 203, respective opening through which the base material F passes are formed. The deposition unit C21 according to this embodiment deposits an atomic layer on both surfaces of the base material F to be conveyed by a roll-to-roll process.

The deposition unit C21 includes a first roller group 210 and a second roller group 220 that is located immediately downstream of the first roller group 210. The first roller group 210 includes a plurality of guide rollers 21A, 21B, and 21C that are arranged so as to change, while supporting the back surface Fb of the base material F to be conveyed by a roll-to-roll process, the conveying direction of the base material F in a stepwise manner. The second roller group 220 includes a plurality of guide rollers 21D, 21E, and 21F that are arranged so as to change, while supporting the front surface Fa of the base material F, the conveying direction of the base material F in a stepwise manner.

Since the guide rollers 21A to 21F each have the same configuration as that of the guide rollers 11A to 11D described in the first embodiment, a detailed description of the guide rollers 21A to 21F will be omitted here.

The deposition unit C21 includes a plurality of ALD heads 22A, 22B, 22C, and 22D. The ALD head 22A is disposed between the guide roller 21A and the guide roller 21B, and the ALD head 22B is disposed between the guide roller 21B and the guide roller 21C. The ALD heads 22A and 22B each face the front surface Fa of the base material F through a predetermined gap (clearance), and discharge, towards the front surface Fa of the base material F, various raw material gases for depositing an ALD layer.

On the other hand, the ALD head 22C is disposed between the guide roller 21D and the guide roller 21E, and the ALD head 22D is disposed between the guide roller 21E and the guide roller 21F. The ALD heads 22C and 22D each face the back surface Fb of the base material F through a predetermined gap (clearance), and discharge, towards the front surface Fa of the base material F, various raw material gases for depositing an ALD layer.

Since the ALD heads 22A to 22D each have the same configuration as that of the ALD heads 12A to 12C described in the first embodiment, a detailed description of the ALD heads 22A to 22D will be omitted here.

The deposition unit C21 includes a plurality of heater units 23A, 23B, 23C, and 23D. The heater units 23A to 23D are disposed so as to face the ALD heads 22A to 22D, respectively, across the base material F. Since the heater units 23A to 23D each have the same configuration as that of the heater units 13A to 13C described in the first embodiment, a detailed description of the heater units 23A to 23D will be omitted here.

The deposition unit C21 further includes a processing unit 28 that performs surface processing on the both surfaces of the base material F. The processing unit 28 is placed on the conveying path of the base material F between the first roller group 210 and the second roller group 220. In this embodiment, the processing unit 28 includes a pair of processing units 28a and 28b that are disposed across the base material F to be conveyed between the guide roller 21C and the guide roller 21D.

The processing unit 28a faces the front surface Fa of the base material F, and the processing unit 28b faces the back surface Fb of the base material F. The processing units 28a and 28b have a function of removing dust attached to the front surface Fa and the back surface Fb of the base material F, or a function of removing charges on the front surface Fa and the back surface Fb of the base material F. Configurations of the processing units 28a and 28b are not particularly limited and may be a discharge mechanism such as corona treatment, for example. Accordingly, since dust or the like attached during deposition processing on the front surface Fa of the base material F can be removed, it is possible to properly perform deposition processing on the back surface Fb of the base material F.

The unwind unit C22 and the wind-up unit C23 have the same configurations as those of the first embodiment. In this embodiment, a pre-processing unit 25 and a post-processing unit 26 are different from the first embodiment in that UV cured resin discharge units are placed on the both surface sides of the base material F to form an UV resin layer on the both surfaces of the base material F, for example.

Also in the atomic layer deposition apparatus 200 according to this embodiment configured as described above, it is possible to achieve the same operation as that of the first embodiment. Moreover, according to this embodiment, it is possible to form an ALD film having a predetermined thickness on the both surfaces of the base material F conveyed by a roll-to-roll process.

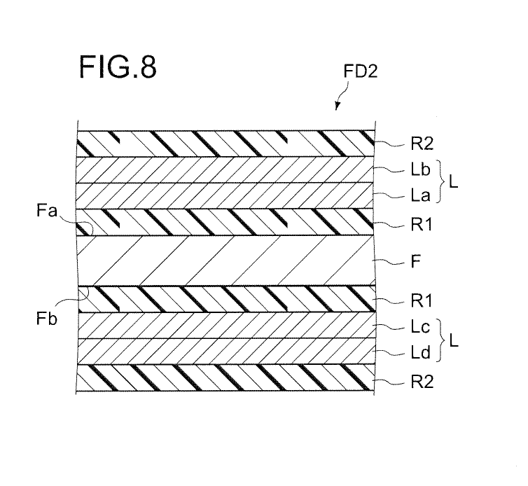

FIG. 8 is a schematic cross-sectional view showing a configuration example of a film device made by the atomic layer deposition apparatus 200. A film device FD2 shown in the figure has a laminate configuration in which, on the front surface Fa of the base material F, the base layer (under coat layer) R1, the ALD layers La and Lb, the protective layer (top coat layer) R2 are formed in the stated order, and, on the back surface Fb of the base material F, the base layer R1, the ALD layer Lc and an ALD layer Ld, and the protective layer R2 are formed in the stated order.

The base layer R1 includes UV cured resin that has been formed in the unwind unit C22. The ALD layers La and Lb are multilayers including aluminum oxide that have been formed by passing through the ALD heads 22A and 22B, respectively, in the deposition units C21. Similarly, the ALD layers Lc and Ld are multilayers including aluminum oxide that have been formed by passing through the ALD heads 22C and 22D, respectively. The protective layer R2 includes UV cured resin that has been formed in the wind-up unit C23. A film device configured as described above may be applied as a water vapor barrier film, for example.

### Third Embodiment

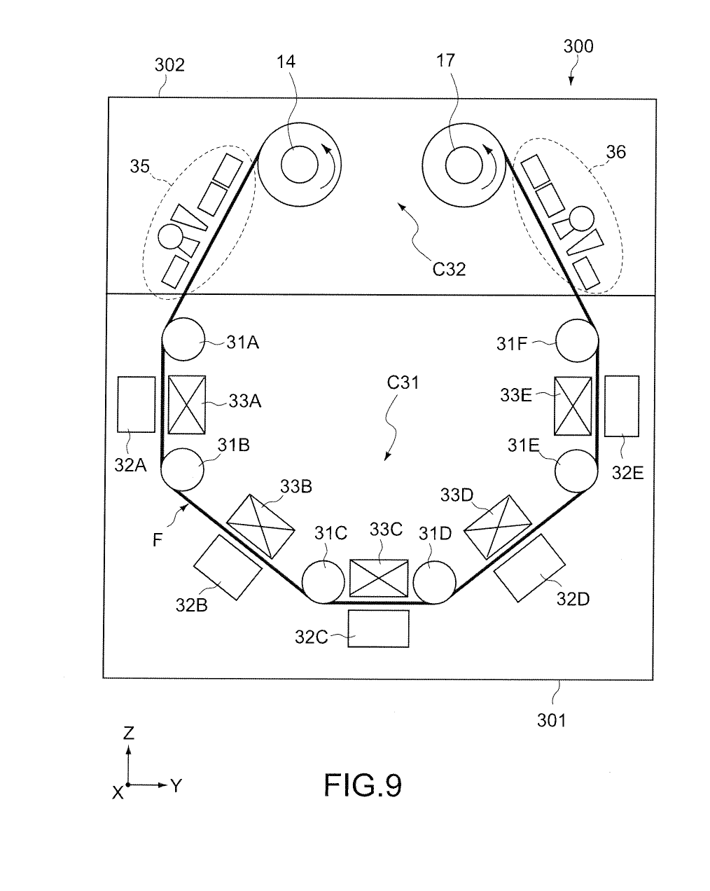

FIG. 9 is a schematic configuration diagram of an atomic layer deposition apparatus according to a third embodiment of the present disclosure. In this embodiment, a description of the same configuration and operation as those according to the first embodiment will be omitted or simplified, and a different component from the first embodiment will be described mainly.

An atomic layer deposition apparatus 300 according to this embodiment includes a first chamber 301 and a second chamber 302. In the first chamber 301, a deposition unit C31 including guide rollers, ALD heads, and the like, is housed. In the second chamber 302, an unwind/wind-up unit C32 including an unwind roller that supplies the base material F to the deposition unit C31, a wind-up roller that winds up the base material F from the deposition unit C31, and the like, is housed. Between the first chamber 301 and the second chamber 302, openings through which the base material F passes are &limed. The deposition unit C31 according to this embodiment deposits an atomic layer on one surface of the base material F conveyed by a roll-to-roll process.

The deposition unit C31 includes a plurality of guide rollers 31A, 31B, 31C, 31D, 31E, and 31F that are arranged so as to change, while supporting the back surface Fb of the base material F to be conveyed by a roll-to-roll process, the conveying direction of the base material F in a stepwise manner. In this embodiment, the plurality of guide rollers 31A to 31F are arranged so as to form a conveying path, having a substantially circular shape, of a base material in the first chamber 301. Since the guide rollers 31A to 31F each have the same configuration as that of the guide rollers 11A to 11D described in the first embodiment, a detailed description of the guide rollers 31A to 31F will be omitted here.

The deposition unit C31 includes a plurality of ALD heads 32A, 32B, 32C, 32D, and 32E. The ALD head 32A is disposed between the guide roller 31A and the guide roller 31B, and the ALD head 32B is disposed between the guide roller 31B and the guide roller 31C. The ALD head 32C is disposed between the guide roller 31C and the guide roller 31D, and the ALD head 32D is disposed between the guide roller 31D and the guide roller 31E. Then, The ALD head 32E is disposed between the guide roller 31E and the guide roller 31F.

The ALD heads 32A to 32E each face the front surface Fa of the base material F through a predetermined gap (clearance), and discharge, towards the front surface Fa of the base material F, various raw material gases for depositing an ALD layer. Since the ALD heads 32A to 32E each have the same configuration as that of the ALD heads 12A to 12C described in the first embodiment, a detailed description of the ALD heads 32A to 32E will be omitted here.

The deposition unit C31 includes a plurality of heater units 33A, 33B, 33C, 33D, and 33E. The heater units 33A to 33E are disposed so as to face the ALD heads 32A to 32E, respectively, across the base material F. Since the heater units 33A to 33E each have the same configuration as that of the heater units 13A to 13C described in the first embodiment, a detailed description of the heater units 33A to 33E will be omitted here.

The unwind/wind-up unit C32 includes the unwind roller 14, a pre-processing unit 35, a post-processing unit 36, and the wind-up roller 17. The pre-processing unit 35 and the post-processing unit 36 have the same configurations as those of the pre-processing unit 15 and the post-processing unit 16, respectively, described in the first embodiment.

Also in the atomic layer deposition apparatus 300 according to this embodiment configured as described above, it is possible to achieve the same operation as that of the first embodiment. Moreover, according to this embodiment, since both the unwind roller 14 and wind-up roller 17 are housed in the second chamber 302, it is possible to downsize the entire apparatus or simplify a configuration of a vacuum pumping system.

### Fourth Embodiment

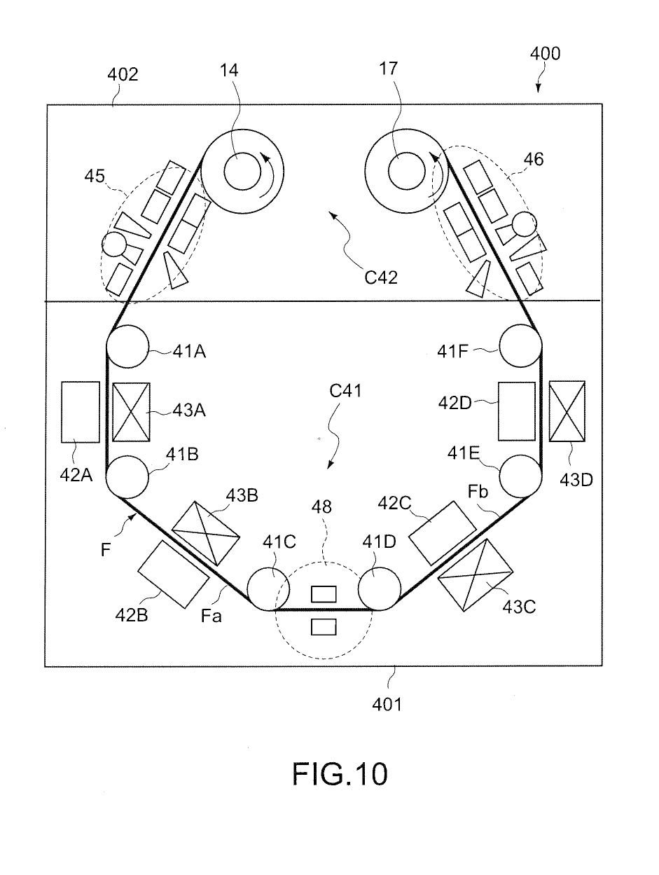

FIG. 10 is a schematic configuration diagram of an atomic layer deposition apparatus according to a fourth embodiment of the present disclosure. In this embodiment, a description of the same configuration and operation as those according to the first embodiment will be omitted or simplified, and a different component from the first embodiment will be described mainly.

An atomic layer deposition apparatus 400 according to this embodiment includes a first chamber 401 and a second chamber 402. In the first chamber 401, a deposition unit C41 including guide rollers, ALD heads, and the like, is housed. In the second chamber 402, an unwind/wind-up unit C42 including an unwind roller that supplies the base material F to the deposition unit C41, a wind-up roller that winds up the base material F from the deposition unit C41, and the like, is housed. Between the first chamber 401 and the second chamber 402, openings through which the base material F passes are formed. The deposition unit C41 according to this embodiment deposits an atomic layer on the both surfaces of the base material F conveyed by a roll-to-roll process.

The deposition unit C41 includes a first roller group and a second roller group that is located immediately downstream of the first roller group. The first roller group includes a plurality of guide rollers 41A, 41B, and 41C that are arranged so as to change, while supporting the back surface Fb of the base material F to be conveyed by a roll-to-roll process, the conveying direction of the base material F in a stepwise manner. The second roller group includes a plurality of guide rollers 41D, 41E, and 41F that are arranged so as to change, while supporting the front surface Fa of the base material F, the conveying direction of the base material F in a stepwise manner.

Since the guide rollers 41A to 41F each have the same configuration as that of the guide rollers 11A to 11D described in the first embodiment, a detailed description of the guide rollers 41A to 41F will be omitted here.

The deposition unit C41 includes a plurality of ALD heads 42A, 42B, 42C, and 42D. The ALD head 42A is disposed between the guide roller 41A and the guide roller 41B, and the ALD head 42B is disposed between the guide roller 41B and the guide roller 41C. The ALD head 42C is disposed between the guide roller 41D and the guide roller 41E, and the ALD head 42D is disposed between the guide roller 41E and the guide roller 41F.

The ALD heads 42A and 42B each face the front surface Fa of the base material F through a predetermined gap (clearance), and discharge, towards the front surface Fa of the base material F, various raw material gases for depositing an ALD layer. On the other hand, the ALD heads 42C and 42D each face the back surface Fb of the base material F through a predetermined gap (clearance), and discharge, towards the back surface Fb of the base material F, various raw material gases for depositing an ALD layer. Since the ALD heads 42A to 42D each have the same configuration as that of the ALD heads 12A to 12C described in the first embodiment, a detailed description of the ALD heads 42A to 42D will be omitted here.

The deposition unit C41 includes a plurality of heater units 43A, 43B, 43C, and 43D. The heater units 43A to 43D are disposed so as to face the ALD heads 42A to 42D, respectively, across the base material F. Since the heater units 43A to 43D each have the same configuration as that of the heater units 13A to 13C described in the first embodiment, a detailed description of the heater units 43A to 43D will be omitted here.

The deposition unit C41 further includes a processing unit 48 that performs surface processing on the both surfaces of the base material F. The processing unit 48 is placed on the conveying path of the base material F between the guide roller 41C and the guide roller 41D. In this embodiment, since the processing unit 48 has the same configuration as that of the processing unit 28 described in the first embodiment, a detailed description of the processing unit 48 will be omitted here.

The unwind/wind-up unit C42 includes the unwind roller 14, a pre-processing unit 45, a post-processing unit 46, and the wind-up roller 17. The pre-processing unit 45 and the post-processing unit 46 have the same configurations as those of the pre-processing unit 25 and the post-processing unit 26, respectively, described in the second embodiment.

Also in the atomic layer deposition apparatus 400 according to this embodiment configured as described above, it is possible to achieve the same operation as that of the first embodiment. Moreover, according to this embodiment, it is possible to form an ALD film having a predetermined thickness on the both surfaces of the base material F conveyed by a roll-to-roll process. Furthermore, according to this embodiment, since both the unwind roller 14 and wind-up roller 17 are housed in the second chamber 402, it is possible to downsize the entire apparatus or simplify a configuration of a vacuum pumping system.

Although the embodiments of the present disclosure have been described above, the embodiments of the present disclosure are not limited to the above-mentioned embodiments and various modifications can be made without departing from the gist of the present disclosure.

For example, in the above-mentioned embodiments, although an atomic layer deposition apparatus has been described as an example of a self-limiting reaction deposition apparatus, the present disclosure is not limited to this. The present disclosure may also be applied to a molecular layer deposition (MLD) apparatus. The molecular layer deposition apparatus is an apparatus that forms a thin film by the same operating principle (self-limiting reaction) as that of the atomic layer deposition apparatus. In the molecular layer deposition apparatus, a material of a film to be fowled differs depending on a precursor (raw material gas). Typically, the molecular layer deposition apparatus is used for deposition of an organic molecular layer.

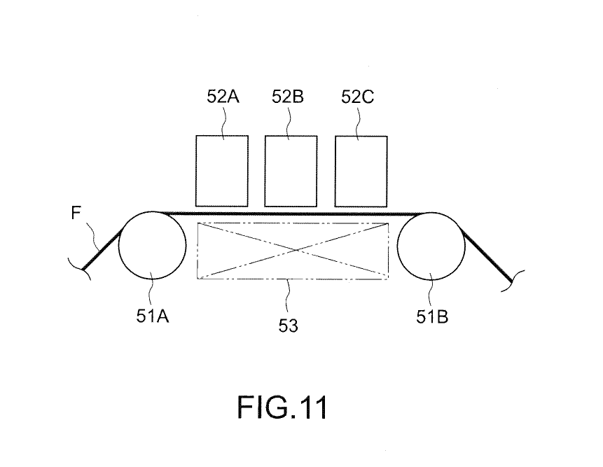

Moreover, in the above-mentioned embodiments, the number of the guide rollers or the ALD heads to be placed in the deposition unit is not limited to the examples described above, and can be changed as appropriate depending on the size of the apparatus and so on. Further, in the above-mentioned embodiments, although the ALD heads are disposed one by one between the guide rollers adjacent to each other, for example, as shown in FIG. 11, a plurality of ALD heads 52A, 52B, and 52C may be disposed between a guide roller 51A and 51B. In this case, one heater unit 53 may be disposed with respect to the ALD heads 52A to 52C, as shown in the figure. Alternatively, a plurality of heater units 53 may be displaced with respect to the respective ALD heads 52A to 52C individually.

Moreover, in the above-mentioned embodiments, although a convection system in which the base material is heated by discharging, towards the base material, the nitrogen gas heated to a predetermined temperature is employed as the heater unit, the base material may be heated by thermal conduction from the heater unit brought into contact with the base material directly. On the other hand, in a case where the inside of the deposition chamber is in a vacuum atmosphere, a radiative heating system that uses an infrared lamp or the like may be employed. It should be noted that the entire chamber may be configured of a thermostatic bath, instead of using the heater unit.

Furthermore, a mechanism that is capable of automatically holding or adjusting the gap (clearance) formed between the ALD head and the base material may be provided. In the mechanism, for example, a rotation speed of the guide roller or discharge pressure of fluid to be discharged from the heater unit may be adjusted. Alternatively, a mechanical/electrostatic means that is different from the above-mentioned examples may be employed.

Furthermore, in the above-mentioned embodiments, although a water vapor barrier film has been described as an example of a thin film to be formed on one surface or both surfaces of the base material F, the present disclosure may also be applied to formation of, in addition to the water vapor barrier film, a surface protection film (antioxidant film) of various devices, a metal film such as an electrode film and a barrier metal film, a dielectric film such as a high-dielectric-constant film and a low-dielectric-constant film, a piezoelectric film, a graphene film, a carbon nanotube film, a surface layer of a separator for a non-aqueous electrolyte rechargeable battery, and the like.

It should be noted that the present disclosure may also employ the following configurations.

(1) A self-limiting reaction deposition apparatus, including:

a first guide roller configured to change, while supporting a first surface of a base material conveyed by a roll-to-roll process, a conveying direction of the base material from a first direction to a second direction that is not parallel to the first direction;

a second guide roller configured to change, while supporting the first surface of the base material, the conveying direction of the base material from the second direction to a third direction that is not parallel to the second direction; and

at least one first head that is disposed between the first guide roller and the second guide roller, faces a second surface opposite to the first surface of the base material, and is configured to discharge, towards the second surface, a raw material gas for self-limiting reaction deposition.

(2) The self-limiting reaction deposition apparatus according to (1), in which

the at least one first head includes a gas discharging surface and forms a thin film on the second surface between the first guide roller and the second guide roller, the gas discharging surface including a plurality of head portions capable of individually discharging a plurality of types of raw material gases and being parallel to the second direction, the thin film having at least one atomic layer.

(3) The self-limiting reaction deposition apparatus according to (1) or (2), further including

a heater unit that is disposed so as to face the first head across the base material and is configured to be capable of heating the base material to a predetermined temperature.

(4) The self-limiting reaction deposition apparatus according to (3), in which

the heater unit includes a discharge unit that is configured to discharge, towards the second surface of the base material, fluid heated to a predetermined temperature.

(5) The self-limiting reaction deposition apparatus according to any one of (1) to (4), further including:

a third guide roller configured to change, while supporting the first surface, the conveying direction of the base material from the third direction to a fourth direction that is not parallel to the third direction; and

a second head that is disposed between the second guide roller and the third guide roller, faces the second surface of the base material, and is configured to discharge, towards the second surface, the raw material gas for self-limiting reaction deposition.

(6) The self-limiting reaction deposition apparatus according to any one of (1) to (5), in which

the at least one first head includes a plurality of first heads that are disposed between the first guide roller and the second guide roller.

(7) A self-limiting reaction deposition apparatus, including:

a first roller group including a plurality of first guide rollers that are arranged so as to change, while supporting a first surface of a base material conveyed by a roll-to-roll process, a conveying direction of the base material in a stepwise manner; and

a plurality of first heads each of which is disposed between predetermined first guide rollers among the plurality of first guide rollers, faces a second surface opposite to the first surface of the base material, and is configured to discharge, towards the second surface, a raw material gas for self-limiting reaction deposition.

(8) The self-limiting reaction deposition apparatus according to (7), further including:

a second roller group including a plurality of second guide rollers that are arranged so as to change, while supporting the second surface of the base material, the conveying direction of the base material in a stepwise manner;

a plurality of second heads each of which is disposed between predetermined second guide rollers among the plurality of second guide rollers, faces the first surface of the base material, and is configured to discharge, towards the first surface, the raw material gas for self-limiting reaction deposition.

(9) The self-limiting reaction deposition apparatus according to (8), further including

a processing unit that is disposed between the first roller group and the second roller group and is configured to perform a dust removing operation on the first surface of the base material and the second surface of the base material.

(10) The self-limiting reaction deposition apparatus according to (7), further including:

an unwind roller configured to supply the base to the first roller group; and

a wind-up roller configured to wind up the base material to be fed out from the first roller group.

(11) The self-limiting reaction deposition apparatus according to (10), further including

a processing unit that is disposed between the unwind roller and the first roller group and is configured to perform a dust removing operation on the first surface of the base material.

(12) The self-limiting reaction deposition apparatus according to (7), further including

a chamber configured to house the first roller group and the plurality of first heads.

(13) A self-limiting reaction deposition method, including:

conveying, while supporting a first surface of a base material conveyed by a roll-to-roll process by a plurality of guide rollers, the base material so as to change a conveying direction in a stepwise manner; and

depositing thin films successively on a second surface opposite to the first surface of the base material by discharging a raw material gas for self-limiting reaction deposition from a plurality of heads each of which is disposed between predetermined guide rollers among the plurality of guide rollers, the thin films having at least one atomic layer.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The application is claimed as follows:

1. A self-limiting reaction deposition apparatus, comprising:
a first guide roller configured to change, while supporting a first surface of a base material conveyed by a roll-to-roll process, a conveying direction of the base material from a first direction to a second direction that is not parallel to the first direction;
a second guide roller configured to change, while supporting the first surface of the base material, the conveying direction of the base material from the second direction to a third direction that is not parallel to the second direction; and
at least one first head that is disposed between the first guide roller and the second guide roller, faces a second surface opposite to the first surface of the base material, and is configured to discharge, towards the second surface, a raw material gas for self-limiting reaction deposition.

2. The self-limiting reaction deposition apparatus according to claim 1, wherein
the at least one first head includes a gas discharging surface and forms a thin film on the second surface between the first guide roller and the second guide roller, the gas discharging surface including a plurality of head portions capable of individually discharging a plurality of types of raw material gases and being parallel to the second direction, the thin film having at least one atomic layer.

3. The self-limiting reaction deposition apparatus according to claim 1, further comprising
a heater unit that is disposed so as to face the first head across the base material and is configured to be capable of heating the base material to a predetermined temperature.

4. The self-limiting reaction deposition apparatus according to claim 3, wherein
the heater unit includes a discharge unit that is configured to discharge, towards the second surface of the base material, fluid heated to a predetermined temperature.

5. The self-limiting reaction deposition apparatus according to claim 1, further comprising:
a third guide roller configured to change, while supporting the first surface, the conveying direction of the base material from the third direction to a fourth direction that is not parallel to the third direction; and
a second head that is disposed between the second guide roller and the third guide roller, faces the second surface of the base material, and is configured to discharge, towards the second surface, the raw material gas for self-limiting reaction deposition.

6. The self-limiting reaction deposition apparatus according to claim 1, wherein
the at least one first head includes a plurality of first heads that are disposed between the first guide roller and the second guide roller.

7. A self-limiting reaction deposition apparatus, comprising:
a first roller group including a plurality of first guide rollers that are arranged so as to change, while supporting a first surface of a base material conveyed by a roll-to-roll process, a conveying direction of the base material in a stepwise manner; and
a plurality of first heads each of which is disposed between predetermined first guide rollers among the plurality of first guide rollers, faces a second surface opposite to the first surface of the base material, and is configured to discharge, towards the second surface, a raw material gas for self-limiting reaction deposition.

8. The self-limiting reaction deposition apparatus according to claim 7, further comprising:
a second roller group including a plurality of second guide rollers that are arranged so as to change, while supporting the second surface of the base material, the conveying direction of the base material in a stepwise manner;
a plurality of second heads each of which is disposed between predetermined second guide rollers among the plurality of second guide rollers, faces the first surface of the base material, and is configured to discharge, towards the first surface, the raw material gas for self-limiting reaction deposition.

9. The self-limiting reaction deposition apparatus according to claim 8, further comprising:
a processing unit that is disposed between the first roller group and the second roller group and is configured to perform a dust removing operation on the first surface of the base material and the second surface of the base material.

10. The self-limiting reaction deposition apparatus according to claim 7, further comprising:
an unwind roller configured to supply the base to the first roller group; and
a wind-up roller configured to wind up the base material to be fed out from the first roller group.

11. The self-limiting reaction deposition apparatus according to claim 10, further comprising:
a processing unit that is disposed between the unwind roller and the first roller group and is configured to perform a dust removing operation on the first surface of the base material.

12. The self-limiting reaction deposition apparatus according to claim 7, further comprising:
a chamber configured to house the first roller group and the plurality of first heads.

13. A self-limiting reaction deposition method, comprising:
conveying, while supporting a first surface of a base material conveyed by a roll-to-roll process by a plurality of guide rollers, the base material so as to change a conveying direction in a stepwise manner; and
depositing thin films successively on a second surface opposite to the first surface of the base material by discharging a raw material gas for self-limiting reaction deposition from a plurality of heads each of which is disposed between predetermined guide rollers among the plurality of guide rollers, the thin films having at least one atomic layer.
